(19) United States
(12) Patent Application Publication
(10) Pub. No.: US 2007/0067702 A1
(43) Pub. Date: Mar. 22, 2007

(54) METHOD AND APPARATUS FOR SYNDROME GENERATION

(76) Inventors: Kuo-Lung Chien, Taipei City (TW); Ching-Wen Hsueh, I-Lan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/162,278

(22) Filed: Sep. 5, 2005

(51) Int. Cl. H03M 13/00

(52) U.S. Cl. 714/785

(57) ABSTRACT

A method of syndrome generation for an error correction code (ECC) block having M columns by N rows with both M and N are greater than 1 includes storing a sub-block of the ECC block into a data memory, reading a plurality of symbols of a column of the sub-block from the data memory with at least one symbol being read during each reading cycle, and updating a plurality of syndromes corresponding to the column of the sub-block according to the plurality of symbols read from the data memory.

### BACKGROUND OF THE INVENTION

The present invention relates to error correction techniques, and more particularly, to syndrome generation methods and apparatus for data with a block configuration.

In data storage systems, error detection and correction mechanisms play an important role in improving the correctness of data. For example, symbols read from an optical medium are typically arranged into a block format for decoding according to industry standard optical storage techniques. FIG. 1 shows a typical ECC block 100 of an industry standard digital versatile disc (DVD) or a high definition DVD (HD-DVD). As illustrated, the symbols in the ECC block 100 are arranged into 208 rows with 182 columns. Each row of the ECC block 100 has ten symbols for providing so-called inner parity (PI). For example, symbols B_{0,172} through B_{0,181} are the inner parity of the fist row of the ECC block 100. In addition, sixteen rows of the ECC block 100 are provided for so-called outer parity (PO). For example, symbols B_{192,0} through B_{207,0} are the outer parity of the first column of the ECC block 100. The 16 rows of outer parity are interleaved with 192 data rows; that is, there is 1 row of outer parity after each set of 12 data rows.

The symbols of the ECC block 100 from an optical disc such as a DVD or a HD-DVD are typically stored in a DRAM and must be checked for errors and corrected for later use. The error detection and correction operations for the ECC block 100 are divided into two phases known as PI decoding and PO decoding. In the PI decoding phase, the conventional error detection and correction operation corrects errors of the ECC block 100 row by row based on PI parity symbols. PI corrected symbols are then written to the DRAM to update the ECC block 100. Specifically, the symbols of the ECC block 100 are accessed along a direction D1 (i.e., along the row direction) in the PI decoding phase.

In the PO decoding phase, the conventional error detection and correction operation corrects errors of the ECC block 100 column by column in accordance with PO parity symbols. The error correction operation is performed in a column basis for code sequences in a direction D2, i.e. in the column direction. For each column, the symbols are processed by syndrome generation logic to generate syndromes of the column. As is well known in the art, the error locations and error values of the column are calculated based on the syndromes of the column, so that the errors within the symbols of the column can be corrected according to the error locations and error values. The calculations of the error locations and error values are very well known in the art and the details are therefore omitted here. Afterwards, PO corrected symbols are applied to the DRAM to update the ECC block 100.

Although the error correction operation is performed along the direction D2 in the PO decoding phase, the symbols of the ECC block 100 are not read along the direction D2 but are instead read along the direction D1. In order to access the symbols of a same column, a discontinuous access (a jump) of the DRAM must be made from one row to another row. Unfortunately, these discontinuous accesses result in page misses, and each page miss causes a penalty being an increased latency.

One conventional method of reducing the latency penalty is to process multiple columns at the same time or to update whole syndrome per cycle. To realize this goal, the syndrome generation logic is typically duplicated, one set for each column or use a memory with wide bandwidth to update whole syndrome. Unfortunately, such an arrangement requires significant layout area or increases the hardware cost.

In view of the foregoing, it can be appreciated that there is a need to improve the syndrome generation efficiency while avoiding the layout area and cost penalties.

### SUMMARY OF THE INVENTION

It is therefore an objective of the claimed invention to provide high-speed syndrome generation method and apparatus with low cost to solve the above-mentioned problems.

An exemplary embodiment of a method of syndrome generation for an error correction code (ECC) block is disclosed comprising: storing a sub-block of the ECC block into a data memory, wherein the sub-block is M columns by N rows with both M and N being greater than 1; reading a plurality of symbols of a column of the sub-block from the data memory, at least one symbol being read during each reading cycle; and updating a plurality of syndromes corresponding to the column of the sub-block according to the plurality of symbols read from the data memory.

An exemplary embodiment of a syndrome generating device for generating syndromes corresponding to an error correction code (ECC) block is disclosed comprising: a first data memory for storing a sub-block of the ECC block, wherein the sub-block is M columns by N rows with both M and N being greater than 1; a syndrome generator electrically coupled to the data memory for receiving a plurality of symbols of a column of the sub-block from the data memory and for accordingly generating a plurality of updated syndromes corresponding to the column of the sub-block; and a first syndrome memory electrically coupled to the syndrome generator for receiving and storing the updated syndromes from the syndrome generator.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an ECC block of an industry standard digital versatile disc (DVD) or a high definition DVD (HD-DVD) according to the related art.

FIG. 2 is a block diagram of a syndrome generating device according to a first embodiment of the present invention.

FIG. 3 is a flowchart illustrating a method of syndrome generation according to one embodiment of the present invention.

FIG. 4 is a diagram illustrating a symbol write direction for a data memory of FIG. 2 according to one embodiment of the present invention.

FIG. 5 is a diagram illustrating a symbol read direction for the data memory of FIG. 2 according to one embodiment of the present invention.

FIG. 6 is a diagram illustrating a syndrome access direction for a syndrome memory of FIG. 2 according to one embodiment of the present invention.

FIG. 7 is a block diagram of a syndrome generating device according to a second embodiment of the present invention.

FIG. 8 is a block diagram of a syndrome generating device according to a third embodiment of the present invention.

FIG. 9 is a block diagram of a syndrome generating device according to a fourth embodiment of the present invention.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

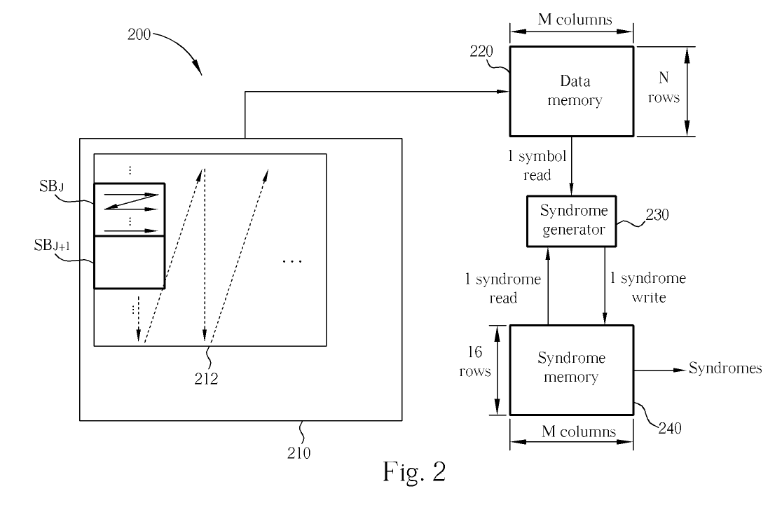

Please refer to FIG. 2, which shows a block diagram of a syndrome generating device 200 according to a first embodiment of the present invention. The syndrome generating device 200 can be applied in various optical storage devices or communication systems. For convenience of description, the syndrome generating device 200 is herein assumed to be applied in an optical storage device such as a DVD/HD-DVD player or recorder. As shown, the syndrome generating device 200 comprises a first memory 210, a data memory 220 electrically coupled to the first memory 210, a syndrome generator 230 electrically coupled to the data memory 220, and a syndrome memory 240 electrically coupled to the syndrome generator 230. In this embodiment, the first memory 210 is arranged for storing an ECC block 212 from an optical storage medium such as a DVD or a HD-DVD. In practice, the first memory 210 may be a DRAM, such as the system memory of the optical storage device, or any other memory. Additionally, the data memory 220 and the syndrome memory 240 may each be implemented as a DRAM, an SDRAM, or an SRAM.

The syndrome generating device 200 is utilized for generating syndromes corresponding to the ECC block 212. The syndromes are utilized for correcting errors of the ECC block 212 during the PO decoding phase. In a DVD/HD-DVD player, for example, an RS decoder (not shown) is typically employed to correct errors of the ECC block 212 in accordance with the syndromes generated from the syndrome generating device 200.

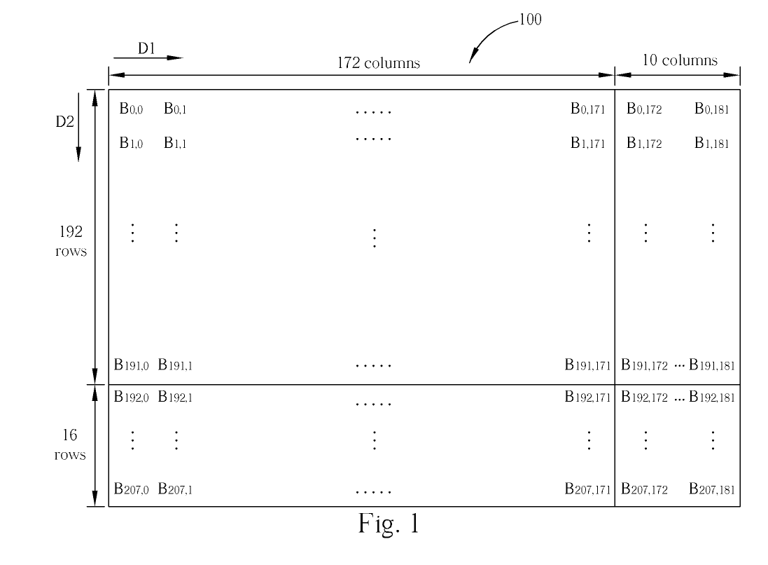

As mentioned in FIG. 1, the ECC block 212 is 182 columns by 208 rows. During syndrome generation operations, the ECC block 212 is divided into a plurality of sub-blocks. In general, the ECC block 212 is divided into sub-blocks of M columns by N rows, where both M and N are greater than one. As an example, in this embodiment, M is 64 while N is 16. Accordingly, both the data memory 220 and the syndrome memory 240 of this embodiment are 64 columns by 16 rows. Since 64 is not a factor of 182, some sub-blocks of the ECC block 212 are 54 columns by 16 rows. Specifically, in this embodiment, the sub-blocks SB₀ through SB₂₅ of the ECC block 212 are 64 columns by 16 rows each while the other sub-blocks SB₂₆ through SB₃₈ are 54 columns by 16 rows each.

The syndrome generating device 200 sequentially processes the plurality of sub-blocks to generate syndromes for the ECC block 212. In this embodiment, the plurality of sub-blocks is sequentially processed along the path and in the direction shown by the dotted arrow in FIG. 2. Since the plurality of sub-blocks are processed sequentially, only one syndrome generator 230 is required for the syndrome generation operations of the ECC block 212.

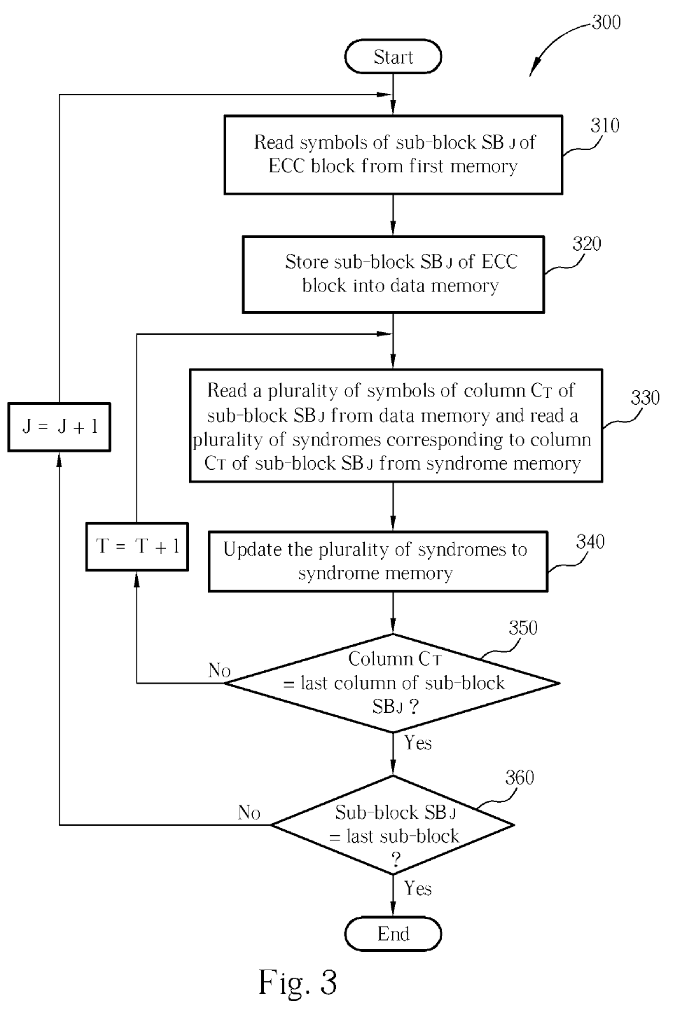

In the syndrome generating device 200, the data memory 220 is for storing a sub-block of the ECC block 212, for example, a sub-block SB_{J} of the ECC block 212. The syndrome generator 230 is utilized for receiving a plurality of symbols of a column of the sub-block SB_{J} from the data memory 220 and for accordingly generating a plurality of updated syndromes corresponding to the column of the sub-block SB_{J}. The syndrome memory 240 is utilized for receiving and storing the updated syndromes from the syndrome generator 230. Note that the term “symbol” as used herein may be an element from Galois field. In practice, each symbol may contain multiple bits of data, e.g., each symbol of this embodiment has 8 bits data. Hereinafter, the operations of the syndrome generating device 200 will be explained in more detail with reference to FIG. 3.

Please refer to FIG. 3, which shows a flowchart 300 illustrating a method of syndrome generation according to one embodiment of the present invention.

In step 310, a memory controller (not shown) of the syndrome generating device 200 reads symbols of a sub-block SB_{J} of the ECC block 212 from the first memory 210. In practice, the memory controller may be a memory controller of the optical storage device. As described before, the sub-block SB_{J} of this embodiment is 64 columns by 16 rows for J being from 0 to 25, and is 54 columns by 16 rows for J being from 26 to 38. In a preferred embodiment, the symbols of the sub-block SB_{J} are sequentially read from the first memory 210 in the row direction of the ECC block 212 as illustrated in FIG. 2 by the solid arrow within the sub-block SB_{J}.

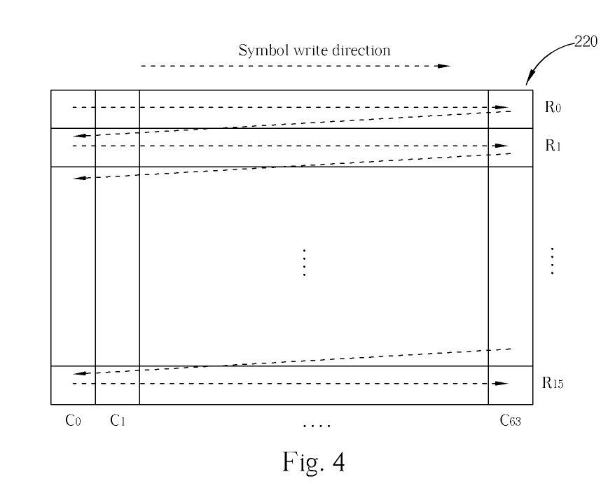

The sub-block SB_{J} is then stored into the data memory 220 in step 320. Symbols of the sub-block SB_{J} can be written into the data memory 220 in any manner. To optimize the writing efficiency, the symbols of the sub-block SB_{J} are preferably sequentially written into the data memory 220 along the direction shown by the dotted arrow illustrated in FIG. 4, i.e. along the row direction of the data memory 220. In the case of 0≦J≦25, the symbols of the sub-block SB_{J} are sequentially written into row R₀ of the data memory 220 from column C₀ through column C₆₃, then into row R₁ from column C₀ through C₆₃, and so forth. In the case of 26≦J≦38, the symbols of the sub-block SB_{J} are sequentially written into row R₀ of the data memory 220 from column C₀ through column C₅₃, then into row R₁ from column C₀ through C₅₃, and so forth. As a result, symbols of a column of the sub-block SB_{J} are stored in a corresponding column of the data memory 220. For example, the symbols of column C₀ of the sub-block SB_{J} are stored in column C₀ of the data memory 220, the symbols of column C₁ of the sub-block SB_{J} are stored in column C₁ of the data memory 220, and so forth.

In step 330, the syndrome generator 230 reads a plurality of symbols of a column C_{T} of the sub-block SB_{J} from the data memory 220 and reads a plurality of syndromes corresponding to the column C_{T} of the sub-block SB_{J} from the syndrome memory 240. As mentioned above, the symbols of the column C_{T} of the sub-block SB_{J} are stored in column C_{T} of the data memory 220. In this embodiment, each column of the syndrome memory 240 stores 16 syndromes corresponding to one column of the sub-block SB_{J}. For example, column C₀ of the syndrome memory 240 stores 16 syndromes corresponding to column C₀ of the sub-block SB_{J}, column C₁ of the syndrome memory 240 stores 16 syndromes corresponding to column C₁ of the sub-block SB_{J}, and so forth. Accordingly, in step 330, the syndrome generator 230 reads symbols from column C_{T} of the data memory 220 and reads syndromes from column C_{T} of the syndrome memory 240.

In step 340, the syndrome generator 230 updates the plurality of syndromes to the syndrome memory 240 according to the plurality of symbols of the column C_{T} of the sub-block SB_{J} read from the data memory 220.

In this embodiment, the 16 syndromes corresponding to the column C_{T} of the sub-block SB_{J} are updated one by one in step 340. Specifically, the syndrome generator 230 reads a current symbol from the column C_{T} of the data memory 220 and reads a current syndrome from the column C_{T} of the syndrome memory 240 during each reading cycle. The syndrome generator 230 then calculates an updated syndrome according to both the current symbol and the current syndrome. Afterwards, the syndrome generator 230 writes the updated syndrome into the column C_{T} of the syndrome memory 240 to replace the current syndrome. The syndrome generator 230 continues this operation for the next one of the 16 syndromes corresponding to the column C_{T} of the sub-block SB_{J} until all of 16 syndromes have been updated.

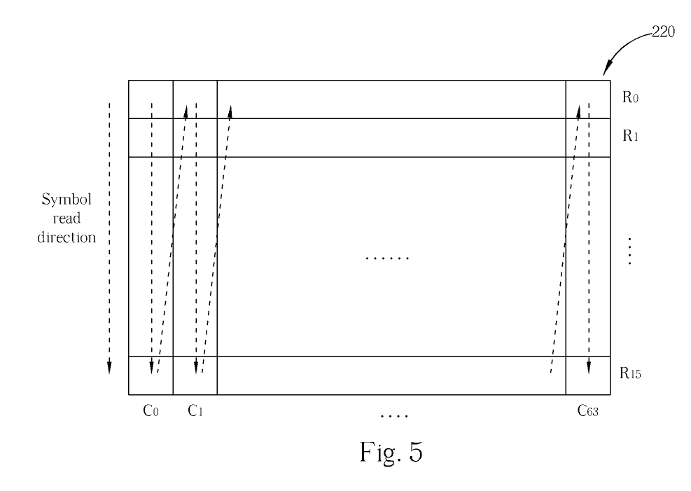

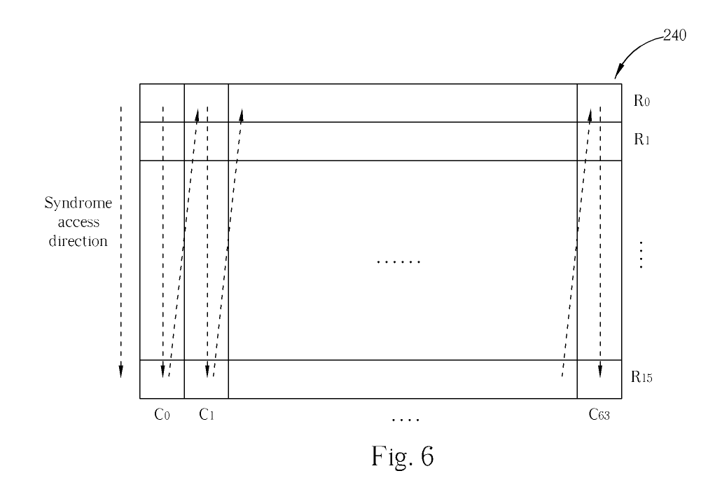

When the 16 syndromes corresponding to the column C_{T} of the sub-block SB_{J} are completely updated, the syndrome generating device 200 performs step 350 to determine if the column C_{T} is a last column of the sub-block SB_{J}. If so, the syndrome generating device 200 proceeds to step 360; otherwise, the syndrome generator 230 repeats steps 330 through 350 for next column C_{T+1} of the sub-block SB_{J} until all 64 columns of the sub-block SB_{J} have been processed. The symbol read direction for the data memory 220 is illustrated by the dotted arrow shown in FIG. 5, and the syndrome access direction for the syndrome memory 240 is illustrated by the dotted arrow shown in FIG. 6.

In step 360, the syndrome generating device 200 determines if the sub-block SB_{J} is the last sub-block of the ECC block 212. If the sub-block SB_{J} is not the last sub-block of the ECC block 212, the syndrome generating device 200 repeats steps 310 through 360 for next sub-block SB_{J+1} until all sub-blocks of the ECC block 212 have been processed.

As in the foregoing description, a current sub-block to be processed is buffered in the data memory 220, and symbols of the current sub-block are applied to the syndrome generator 230 from the data memory 220 instead of from the first memory 210. Accordingly, the latency of reading symbols of the sub-block to update corresponding syndromes is significantly reduced. The latency can be reduced to a minimum level by utilizing an SRAM to implement the data memory 220.

In this embodiment, after thirteen sub-blocks are completely processed, partial syndromes of the ECC block 212 are obtained in the syndrome memory 240. For example, after the first 13 sub-blocks SB₀˜SB₁₂ are processed, the syndromes stored in the syndrome memory 240 can be utilized to perform the error correction operation for the first 64 columns C₀˜C₆₃ of the ECC block 212. Similarly, after the next 13 sub-blocks SB₁₃˜SB₂₅ are processed, syndromes for the next 64 columns C₆₄˜C₁₂₇ of the ECC block 212 are obtained. Finally, after the last 13 sub-blocks SB₂₆˜SB₃₈ are processed, syndromes for the last 54 columns C₁₂₈˜C₁₈₁ of the ECC block 212 are obtained. Accordingly, once thirteen sub-blocks are completely processed, the syndromes stored in the syndrome memory 240 are applied to the RS decoder of the optical storage device.

It should be noted that the symbol writing direction for the data memory 220 shown in FIG. 4 is merely an example rather than a restriction. As will be apparent to those of ordinary skill in the art, the symbols of the sub-block SB_{J} can be written into the data memory 220 in other manners. Of course, when the symbol write direction for the data memory 220 changes, the symbol read direction for the data memory 220 may be correspondingly adjusted. Similarly, the syndrome access direction for the syndrome memory 240 shown in FIG. 6 is also an example rather than a limitation for practical applications of the present invention.

As in the foregoing descriptions, the syndromes stored in the syndrome memory 240 are read sequentially by the syndrome generator 230, where one syndrome is read during each reading cycle. Accordingly, the syndrome memory 240 can be implemented with a one-port memory such as a one-port SRAM. However, this is merely an example implementation of the syndrome memory rather than a limitation. In other embodiments, the syndrome memory 240 could be implemented as a two-port memory or a dual-port memory. As known, each syndrome is one byte in this application. Therefore, the data bus between the syndrome memory 240 and the syndrome generator 230 only requires a width of one byte. In practical implementations, the capacity requirement of the data memory reduces as the data bus width of the syndrome memory increases.

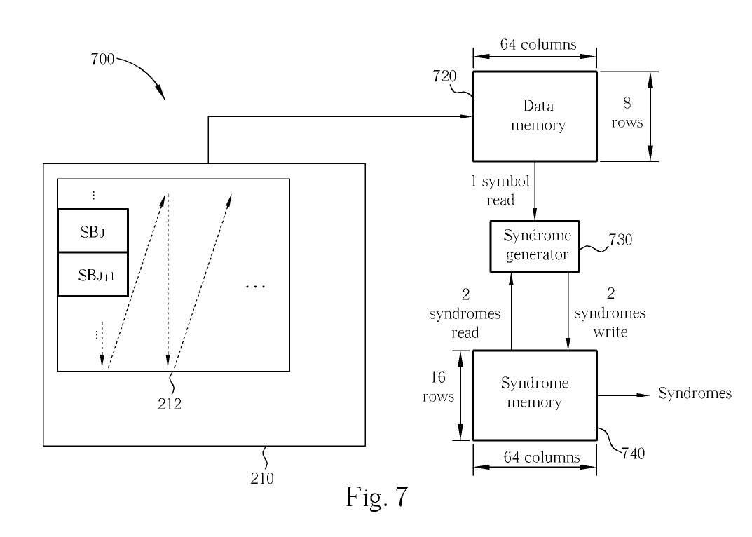

For example, FIG. 7 shows a block diagram of a syndrome generating device 700 according to a second embodiment of the present invention. The syndrome generating device 700 comprises the first memory 210, a data memory 720, a syndrome generator 730, and a syndrome memory 740. In this embodiment, the data bus between the syndrome memory 740 and the syndrome generator 730 has a width of two bytes. Accordingly, the syndrome generator 730 reads a current symbol from the data memory 720 and two current syndromes from the syndrome memory 740 during each reading cycle. Then, the syndrome generator 730 updates the two current syndromes in accordance with the current symbol. As a result, the size of the data memory 720 can be reduced to 64 columns×8 rows. Since the capacity of the data memory 720 is changed, the ECC block 212 is correspondingly divided into smaller sub-blocks. In a preferred embodiment, for example, most sub-blocks of the ECC block 212 are 64 columns by 8 rows and the others are 54 columns by 8 rows. The operations of the syndrome generating device 700 are similar to the syndrome generating device 200 previously mentioned, and further details are therefore omitted for brevity.

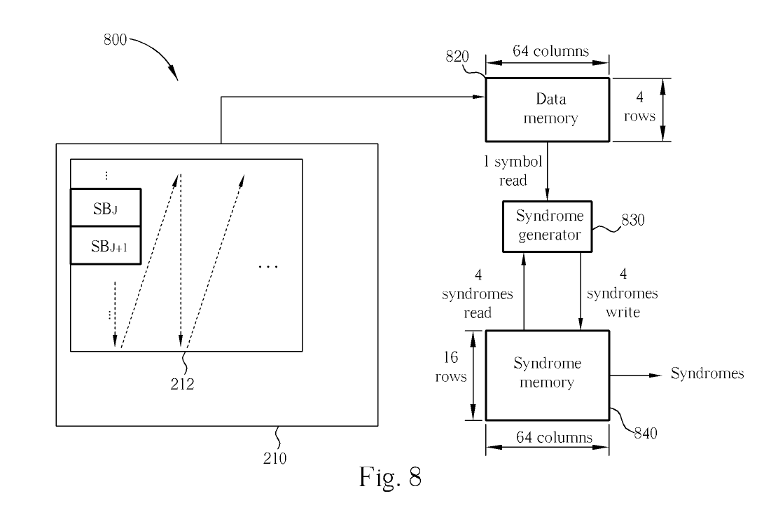

FIG. 8 illustrates a block diagram of a syndrome generating device 800 according to a third embodiment of the present invention. As shown, the syndrome generating device 800 comprises the first memory 210, a data memory 820, a syndrome generator 830, and a syndrome memory 840. In contrast to the foregoing embodiments, the data bus between the syndrome memory 840 and the syndrome generator 830 has a width of four bytes. Therefore, the syndrome generator 830 can read a current symbol from the data memory 820 and four current syndromes from the syndrome memory 840 during each reading cycle, so that the size of the data memory 820 can be reduced to 64 columns×4 rows. Similarly, the ECC block 212 should be correspondingly divided into smaller sub-blocks due to the capacity of the data memory 820 is changed. In a preferred embodiment, for example, most sub-blocks are 64 columns by 4 rows and the others are 54 columns by 4 rows.

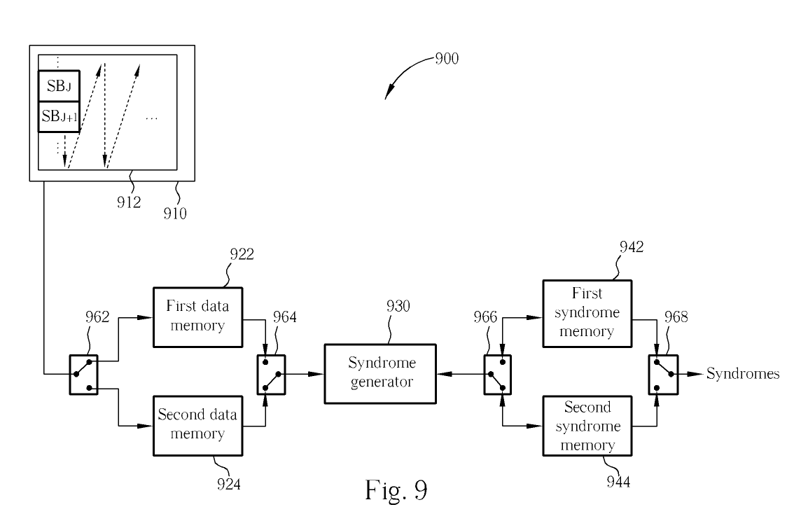

FIG. 9 shows a block diagram of a syndrome generating device 900 according to a fourth embodiment of the present invention. The syndrome generating device 900 comprises a first memory 910, two data memories 922 and 924, a syndrome generator 930, and two syndrome memories 942 and 944. In FIG. 9, four switches 962, 964, 966 and 968 represent selection mechanisms of data flow between blocks. In practice, these selection mechanisms can be implemented with hardware means or software means. The operations of the syndrome generating device 900 are similar to the foregoing embodiments and will be explained with reference to FIG. 3.

In particular, a sub-block SB_{J} of an ECC block 912 is read from the first memory 910 and stored in the first data memory 922 according to steps 310 and 320. Then, the syndrome generator 930 updates syndromes corresponding to the sub-block SB_{J} stored in the first data memory 922 by repeating steps 330 through 350. A difference between the syndrome generating device 900 and the previous embodiments is that a next sub-block SB_{J+1} is loaded into the second data memory 924 while the syndrome generator 930 processes the sub-block SB_{J}. Therefore, after symbols of the sub-block SB_{J} stored in the first data memory 922 are processed, the syndrome generator 930 can read symbols of the next sub-block SB_{J+1} from the second data memory 924 immediately without waiting. Similarly, while the syndrome generator 930 updates syndromes corresponding to the sub-block SB_{J+1} stored in the second data memory 924, a succeeding sub-block SB_{J+2} is loaded into the first data memory 922.

In addition, all the sub-bocks of the ECC block 912 can be defined as multiple columns of sub-blocks. Specifically, suppose that the sub-blocks SB₀ through SB₂₅ of the ECC block 912 are 64 columns by 16 rows each while the other sub-blocks SB₂₆ through SB₃₈ are 54 columns by 16 rows each as well as the first embodiment mentioned before. The first 13 sub-blocks SB₀˜SB₁₂ of the ECC block 912 are herein defined as a first column of sub-blocks, the next 13 sub-blocks SB₁₃˜SB₂₅ are defined as a second column of sub-blocks, and the last 13 sub-blocks SB₂₆˜SB₃₈ are defined as a third column of sub-blocks. Another difference between the syndrome generating device 900 and the prior embodiments is that the two syndrome memories 942 and 944 are alternated to store syndromes for the multiple columns of sub-blocks.

For example, if the first syndrome memory 942 is employed to store the syndromes for the first column of sub-blocks composed of the first 13 sub-blocks SB₀˜SB₁₂ of the ECC block 912, then the second syndrome memory 944 will be employed to store the syndromes for the second column of sub-blocks composed of the next 13 sub-blocks SB₁₃˜SB₂₅. As in the previous description, after the first 13 sub-blocks SB₀˜SB₁₂ are completely processed, the first syndrome memory 942 outputs the syndromes of the first column of sub-blocks to a RS decoder (not shown) to perform the error correction operation for the first 64 columns of the ECC block 912. At the same time, the syndrome generator 930 stores the syndromes of the second column of sub-blocks into the second syndrome memory 944 during the syndrome generation operation for the next 13 sub-blocks SB₁₃˜SB₂₅ of the ECC block 912. After the syndromes for the second column of sub-blocks are completely updated, the second syndrome memory 944 outputs the updated syndromes to the RS decoder, and the syndrome generator 930 stores the syndromes of the third column of sub-blocks into the first syndrome memory 942 during the syndrome generation operation for the last 13 sub-blocks SB₂₆˜SB₃₈ of the ECC block 912.

As a result, by utilizing the two data memories 922, 924 and the two syndrome memories 942 and 944, the syndrome generator 930 can continuously generate syndromes for the ECC block 912 and thereby significantly improving the syndrome generation performance. As an exemplary preferred embodiment, each of the data memories 922, 924 and the syndrome memories 942 and 944 can be implemented as an SRAM, such as a single-port SRAM. In practice, the two data memories 922 and 924 may be replaced by a two-port SRAM. Similarly, the two syndrome memories 942 and 944 can also be replaced by a two-port SRAM.

In practice, the disclosed syndrome generation methods of the present invention can be performed after the PI decoding phase is completed or be performed during the PI decoding phase. In the latter case, it is possible that only a portion of a target ECC block is stored in the first memory (e.g., 210 or 910) while another portion of the target ECC block does not yet be read from the optical storage medium. As long as a current sub-block to be processed by the syndrome generator is stored in the first memory, the syndrome generation methods of the present invention can be performed to generate the syndromes for use in the PO decoding. In other words, the syndrome generation operation for the PO decoding can be performed during the PI decoding phase. As a result, the decoding speed of the PO decoding phase can be thereby greatly improved without influencing the decoding speed of the PI decoding phase. Additionally, the proposed syndrome generation method can be performed on a whole ECC block or on a portion of columns of the ECC block.

In the foregoing embodiments, the symbols of the sub-block stored in the data memory to be processed by the syndrome generator are read from the first memory. This is merely an example rather than a limitation of practical applications of the present invention. In practice, the symbols of the target ECC block read from the optical storage medium are typically buffered in a buffer, which is arranged between the optical storage medium and the first memory, before they are wrote into the first memory. This stage is also referred to as a buffering phase. The PI decoding operation for the target ECC block may be performed in the buffering phase to reduce the bandwidth loading of the first memory. Similarly, the proposed syndrome generation method disclosed previously can be performed in the buffering phase.

For example, the symbols of the current sub-block to be stored in the data memory can instead be retrieved from the buffer in the buffering phase. Then, the disclosed syndrome generator can generate the syndromes of the target ECC block according to the symbols stored in the data memory as well as the foregoing embodiments and put the updated syndromes in the syndrome memory. After the target ECC block is wrote into the first memory, the error correction for the column direction of the target ECC block can be performed according to the updated syndromes stored in the syndrome memory without reading symbols from the first memory to the data memory to generate required syndromes. Obviously, the bandwidth requirement of the first memory can be therefore significantly reduced when correcting errors in the column direction of the target ECC block. In practice, the disclosed syndrome generation method can also be applied in data read from a blue-ray disc to reduce the memory bandwidth requirement of a reproducing system.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of syndrome generation for an error correction code (ECC) block, the method comprising:
(a) storing a sub-block of the ECC block into a data memory, wherein the sub-block is M columns by N rows with N being greater than 1;
(b) reading a plurality of symbols of a column of the sub-block from the data memory, at least one symbol being read during each reading cycle; and
(c) updating a plurality of syndromes corresponding to the column of the sub-block according to the plurality of symbols read from the data memory.

2. The method of claim 1, wherein the data memory is an SRAM.

3. The method of claim 1, wherein at least a portion of the ECC block including the sub-block is stored in a first memory, and step (a) further comprises:
sequentially reading symbols of the sub-block to be stored in the data memory from the first memory along a row direction of the ECC block.

4. The method of claim 3, wherein the first memory is a DRAM.

5. The method of claim 1, wherein step (c) further comprises:
(c1) reading the plurality of syndromes from a syndrome memory, at least one syndrome being read during each reading cycle; and
(c2) when one of the plurality of syndromes is updated, writing the updated syndrome into the syndrome memory.

6. The method of claim 5, wherein the syndrome memory is an SRAM.

7. The method of claim 1, further comprising:
(d) determining if the column is a last column of the sub-block; and
(e) repeating steps (b) through (d) for a next column of the sub-block if the column is not the last column of the sub-block.

8. The method of claim 7, further comprising:
(f) if the column is the last column of the sub-block, determining if the sub-block is a last sub-block of the ECC block; and
(g) repeating steps (a) through (f) for a next sub-block of the ECC block if the sub-block is not the last sub-block of the ECC block.

9. The method of claim 1, wherein the plurality of syndromes corresponding to the column of the sub-block is updated one by one in step (c).

10. The method of claim 1, further comprising:
before syndromes corresponding to the sub-block are completely updated, storing a next sub-block of the ECC block from the first memory.

11. The method of claim 1, wherein step (a) further comprises:
buffering at least a portion of the ECC block including the sub-block retrieved from an optical storage medium in a buffer; and
reading symbols of the sub-block to be stored in the data memory from the buffer.

12. A syndrome generating device for generating syndromes corresponding to an error correction code (ECC) block, the syndrome generating device comprising:
a first data memory for storing a sub-block of the ECC block, wherein the sub-block is M columns by N rows with N being greater than 1;
a syndrome generator electrically coupled to the data memory for receiving a plurality of symbols of a column of the sub-block from the data memory and for accordingly generating a plurality of updated syndromes corresponding to the column of the sub-block; and
a first syndrome memory electrically coupled to the syndrome generator for receiving and storing the updated syndromes from the syndrome generator.

13. The syndrome generating device of claim 12, wherein the syndrome generator receives the plurality of symbols from the first data memory at least one symbol during each reading cycle.

14. The syndrome generating device of claim 12, wherein the first data memory is an SRAM.

15. The syndrome generating device of claim 12, wherein the first syndrome memory is an SRAM.

16. The syndrome generating device of claim 12, further comprising:
a first memory electrically coupled to the first data memory for storing at least a portion of the ECC block including the sub-block;
wherein symbols of the sub-block to be stored in the first data memory are sequentially read from the first memory along a row direction of the ECC block.

17. The syndrome generating device of claim 16, wherein the first memory is a DRAM.

18. The syndrome generating device of claim 16, further comprising:
a second data memory electrically coupled between the first memory and the syndrome generator;
wherein before syndromes corresponding to the sub-block are completely updated, the second data memory stores a next sub-block of the ECC block from the first memory.

19. The syndrome generating device of claim 12, wherein the syndrome generator generates the plurality of updated syndromes according to the plurality of symbols from the first data memory and a plurality of syndromes from the first syndrome memory.

20. The syndrome generating device of claim 19, wherein the syndrome generator reads at least one syndrome from the first syndrome memory during each reading cycle.

21. The syndrome generating device of claim 12, wherein the syndrome generator repeats operations for a next column of the sub-block until all the M columns of the sub-block are processed.

22. The syndrome generating device of claim 21, wherein when all the M columns of the sub-block are processed, the syndrome generator repeats operations for a next sub-block of the ECC block.

23. The syndrome generating device of claim 12, further comprising:
a second syndrome memory electrically coupled to the syndrome generator;
wherein the ECC block is defined as K columns of sub-blocks where K is greater than one, and the first and second syndrome memories are alternated to store syndromes for the K columns of sub-blocks.

24. The syndrome generating device of claim 12, further comprising:
a buffer electrically coupled to the first data memory for buffering at least a portion of the ECC block including the sub-block;
wherein symbols of the sub-block to be stored in the first data memory are read from the buffer.
